(19) United States
(12) Patent Application Publication
(10) Pub. No.: US 2012/0212127 A1
(43) Pub. Date: Aug. 23, 2012

(54) ORGANIC LIGHT EMITTING DIODE AND LIGHT EMITTING ELEMENT

(75) Inventors: Ryohei Kakiuchi, Ibaraki-shi (JP); Takahiro Nakai, Ibaraki-shi (JP); Jin Yoshikawa, Ibaraki-shi (JP); Noriyuki Juni, Ibaraki-shi (JP)

(73) Assignee: NITTO DENKO CORPORATION, Ibaraki-shi, Osaka (JP)

(21) Appl. No.: 13/505,128

(22) PCT Filed: Dec. 10, 2010
(86) PCT No.: PCT/JP2010/072232

§ 371 Date: Apr. 30, 2012

(30) Foreign Application Priority Data
Dec. 18, 2009 (JP) 2009-287164

(51) Int. Cl. H05B 33/28

(52) U.S. Cl. 313/504

(57) ABSTRACT

There is provided an organic light emitting diode, wherein in a transparent substrate used therein, the length of a side (upper side) on a transparent electrode layer side is shorter than the length of a side (lower side) on an emission side in a cross section parallel to a short side. Ends of the side (upper side) on the transparent electrode layer side and ends of the side (lower side) on the emission side are connected by straight lines or curved lines. Angles (α,β) formed by side surfaces of the transparent substrate and the side (lower side) on the emission side are larger than 0° and smaller than 90°.

### BACKGROUND OF THE INVENTION

1. Field of the invention

The present invention relates to an organic light emitting diode, and more particularly, relates to a structure of a transparent substrate for an organic light emitting diode. In addition, the present invention relates to a light emitting element formed in combination with an organic light emitting diode.

2. Description of Related Art

FIG. 6 is a schematic plan view of and a cross-sectional view of a typical organic light emitting diode 30 (organic EL) (“All About Organic EL” written by Junji KIDO, Nippon Jitsugyo Publishing Co., Ltd., published on Feb. 20, 2003, p. 47). As shown in FIG. 6, the typical organic light emitting diode 30 has a transparent electrode layer 32 (anode), an organic light emitting layer 33, and a rear electrode layer 34 (cathode) formed by stacking on a transparent substrate 31 (glass substrate). For the transparent electrode layer 32, an indium tin oxide (ITO) is widely used. For the rear electrode layer 34, aluminum and magnesium are widely used. The rear electrode layer 34 is opaque.

When a direct-current voltage is applied between the transparent electrode layer 32 (anode) and the rear electrode layer 34 (cathode), holes injected from the transparent electrode layer 32 and electrons injected from the rear electrode layer 34 are combined in the organic light emitting layer 33 to produce luminescence. Because the rear electrode layer 34 is opaque, light 35 generated in the organic light emitting layer 33 is emitted through the transparent electrode layer 32 and the transparent substrate 31 to the outside (downward).

As another example of an organic light emitting diode, JP 2008-108731 A discloses an organic light emitting diode for displaying still signs and characters. The organic light emitting diode disclosed in JP 2008-108731 A has, not shown, a rear electrode layer formed to have two layers, one of which is intended for sign and character patterns. However, a transparent substrate thereof is not particularly different from the transparent substrate 31 of the organic light emitting diode 30 shown in FIG. 6.

FIG. 7 shows the light 35 generated in the organic light emitting layer 33, which travels inside the transparent substrate 31, in the organic light emitting diode 30 shown in FIG. 6. As for how light generated in the organic light emitting layer 33 travels inside the transparent substrate 31, the same applies to the organic light emitting diode disclosed in JP 2008-108731 A.

The light 35 generated in the organic light emitting layer 33 is not directional, and the light 35 passing through the transparent electrode layer 32 thus travels in various directions inside the transparent substrate 31. The critical angle of light at the boundary between the transparent substrate 31 and the outside (for example, air) is determined by the ratio between the refractive index of the transparent substrate 31 and the refractive index of the outside. Light incident from the inside of the transparent substrate 31 onto the boundary between the transparent substrate 31 and the outside at an angle larger than the critical angle is totally reflected at the boundary between the transparent substrate 31 and the outside.

The light totally reflected at the boundary between the transparent substrate 31 and the outside is then totally reflected at the boundary between the transparent substrate 31 and the transparent electrode layer 32. The light is again totally reflected at the boundary between the transparent substrate 31 and the outside. Of the light 35 generated in the organic light emitting layer 33, the light incident from the inside of the transparent substrate 31 onto the boundary between the transparent substrate 31 and the outside at an angle larger than the critical angle is repeatedly totally reflected as described above, and emitted to the outside from side surfaces 31a, 31b of the transparent substrate 31.

In the organic light emitting diode disclosed in JP 2008-108731 A, the transparent substrate also has the same structure as in the organic light emitting diode 30 shown in FIGS. 6 and 7, a portion of light generated in the organic light emitting layer is thus repeatedly totally reflected, and emitted to the outside from side surfaces of the transparent substrate.

In the conventional organic light emitting diode 30, a portion of the light 35 generated in the organic light emitting layer 33 is repeatedly totally reflected, and emitted to the outside from the side surfaces 31a, 31b of the transparent substrate 31. The conventional organic light emitting diode 30 has a problem of having low light extraction efficiency because it is not possible to use the light emitted to the outside from the side surfaces 31a, 31b of the transparent substrate 31.

The conventional organic light emitting diode 30 is not flexible because a glass substrate is used widely as the transparent substrate 31. Therefore, it is difficult to create a curved light emitting element or a curved display with the use of the conventional organic light emitting diode 30 which is large-sized.

Small-sized conventional organic light emitting diodes 30 can be arranged to create a curved light emitting element or a curved display. However, it is necessary to arrange the organic light emitting diodes 30 in a reticular pattern in order to create a curved light emitting element or a curved display because the conventional organic light emitting diodes 30 typically have a square or nearly square rectangular shape. For this reason, the number of the organic light emitting diodes 30 will be increased, and the wiring will be also complicated. Accordingly, it is not practical to arrange the conventional small-size organic light emitting diodes 30 for creating a curved light emitting element or a curved display.

### SUMMARY OF THE INVENTION

In the conventional organic light emitting diode 30, a portion of the light 35 generated in the organic light emitting layer 33 is repeatedly totally reflected at the boundary between the transparent substrate 31 and the outside and at the boundary between the transparent substrate 31 and the transparent electrode layer 32, and emitted to the outside from the side surfaces 31a, 31b of the transparent substrate 31. The conventional organic light emitting diodes 30 have the problem of having low light extraction efficiency because it is not possible to use the light 35 emitted to the outside from the side surfaces 31a, 31b of the transparent substrate 31.

The conventional organic light emitting diode 30 generally has a square or nearly square rectangular planar shape. In addition, the conventional organic light emitting diode 30 is not flexible because the transparent substrate 31 is a glass plate. For this reason, it is difficult to create a curved light emitting element or a curved display with the use of the conventional organic light emitting diodes 30.

The summary of the present invention is described as follows:

In a first preferred aspect of the present invention, an organic light emitting diode according to the present invention comprises at least a transparent substrate, a transparent electrode layer, an organic light emitting layer, and a rear electrode layer in this order. The organic light emitting diode according to the present invention has a rectangular planar shape, and the length of a long side of the rectangular shape is 5 or more times as long as the length of a short side thereof (the length of the long side is also simply referred to as a length, whereas the length of the short side is also simply referred to as a width). The length of a side of the transparent substrate on the transparent electrode layer side is shorter than the length of a side thereof on an emission side in a cross section parallel to the short side of the transparent substrate. An end of the side of the transparent substrate on the transparent electrode layer side and an end of the side thereof on the emission side are connected by a straight line or a curved line. An angle formed by the straight line or the curved line and the side on the emission side is larger than 0° and smaller than 90°. The angle herein formed by the curved line and the side on the emission side refers to an angle formed by a tangent line on the curved line at the end of the side on the emission side with the side on the emission side.

In a second preferred aspect of the organic light emitting diode according to the present invention, each end of a side of the transparent substrate on the transparent electrode layer side and each end of a side thereof on the emission side are connected by a straight line in a cross section parallel to the short side of the transparent substrate. Therefore, the cross section parallel to the short side of the transparent substrate has a trapezoidal shape.

In a third preferred aspect of the organic light emitting diode according to the present invention, a cross section parallel to the short side of the transparent substrate has a trapezoidal shape, and the trapezoidal shape has a basic angle of 40° to 50° on the emission side.

In a fourth preferred aspect of the organic light emitting diode according to the present invention, the end of the side of the transparent substrate on the transparent electrode layer side and the end of the side thereof on the emission side are connected by a parabola.

In a fifth preferred aspect of the organic light emitting diode according to the present invention, the end of the side of the transparent substrate on the transparent electrode layer side and the end of the side thereof on the emission side are connected by an arc.

In a sixth preferred aspect of the organic light emitting diode according to the present invention, the transparent substrate comprises a flexible polymer film.

In a seventh preferred aspect, a light emitting element according to the present invention is formed by arranging the organic light emitting diode described above in a reed screen fashion.

### ADVANTAGES OF THE INVENTION

The organic light emitting diode according to the present invention controls the path of light, the light being conventionally emitted from the side surfaces of the transparent substrate to the outside and being not available, thereby emitting the light from the front of the transparent substrate. The organic light emitting diodes according to the present invention has a light extraction efficiency higher than conventional efficiencies, because the light emitted from the front of the transparent substrate can be used.

The organic light emitting diode according to the present invention has an elongate rectangular shape. With the use of this shape, the organic light emitting diodes according to the present invention can be arranged parallel in a reed screen fashion to create a large-size curved light emitting element or a curved display (for example, a cylindrical display), even when the transparent substrate is not flexible.

The organic light emitting diodes according to the present invention can use a flexible polymer film for the transparent substrate to create a curved light emitting element or a curved display (for example, a spherical display) which is further free in terms of shape.

### BRIEF DESCRIPTION OF THE DRAWINGS

FIG. 1 is a plan view of and a cross-sectional view of an organic light emitting diode of the present invention;

FIG. 2 is a plan view of and a cross-sectional view of a light emitting element with organic light emitting diodes of the present invention arranged in a planar reed screen fashion;

FIG. 3 is a schematic view of a display with organic light emitting diodes of the present invention arranged in a cylindrical form;

FIG. 4(a) is a cross-sectional view of an organic light emitting diode of the present invention;

FIG. 4(b) is a cross-sectional view of an organic light emitting diode according to the present invention;

FIG. 4(c) is a cross-sectional view of an organic light emitting diode of the present invention;

FIG. 4(d) is a cross-sectional view of a conventional organic light emitting diode;

FIG. 5 is a schematic view of light paths in an organic light emitting diode of the present invention;

FIG. 6 is a plan view of and a cross-sectional view of a conventional organic light emitting diode; and

FIG. 7 is a schematic view of light paths in a conventional organic light emitting diode.

### DESCRIPTION OF THE PREFERRED EMBODIMENTS

### [Organic Light Emitting Diode]

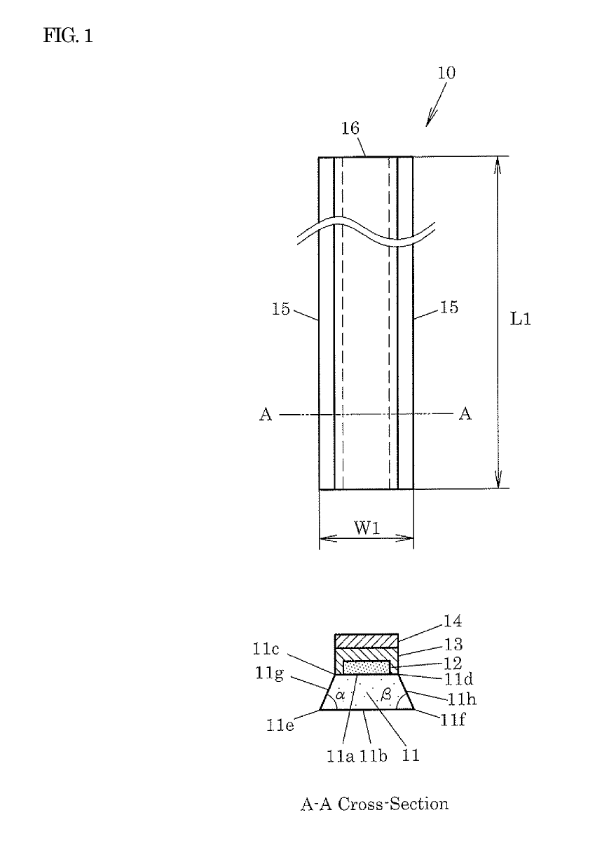

FIG. 1 shows an example of an organic light emitting diode 10 of the present invention. The organic light emitting diode 10 of the present invention includes a transparent substrate 11 which has a specific cross-sectional shape, a transparent electrode layer 12, an organic light emitting layer 13, and a rear electrode layer 14 in this order.

The organic light emitting diode 10 of the present invention may have, not shown, other layers placed between the respective layers mentioned above. For example, a hole injection layer and a hole transport layer may be placed between the transparent electrode layer 12 and the organic light emitting layer 13. Alternatively, an electron transport layer and an electron injection layer may be placed between the organic light emitting layer 13 and the rear electrode layer 14.

As shown in FIG. 1, the organic light emitting diode 10 of the present invention has a planar shape of an elongate rectangle. In the organic light emitting diode of the present invention, the length L1 of a long side 15 is at least 5 or more times, preferably 10 or more times, and further preferably 100 or more times as long as the length (width) W1 of a short side 16. The length (width) W1 of the short side 16 is preferably 10 mm to 100 mm, and further preferably 10 mm to 50 mm.

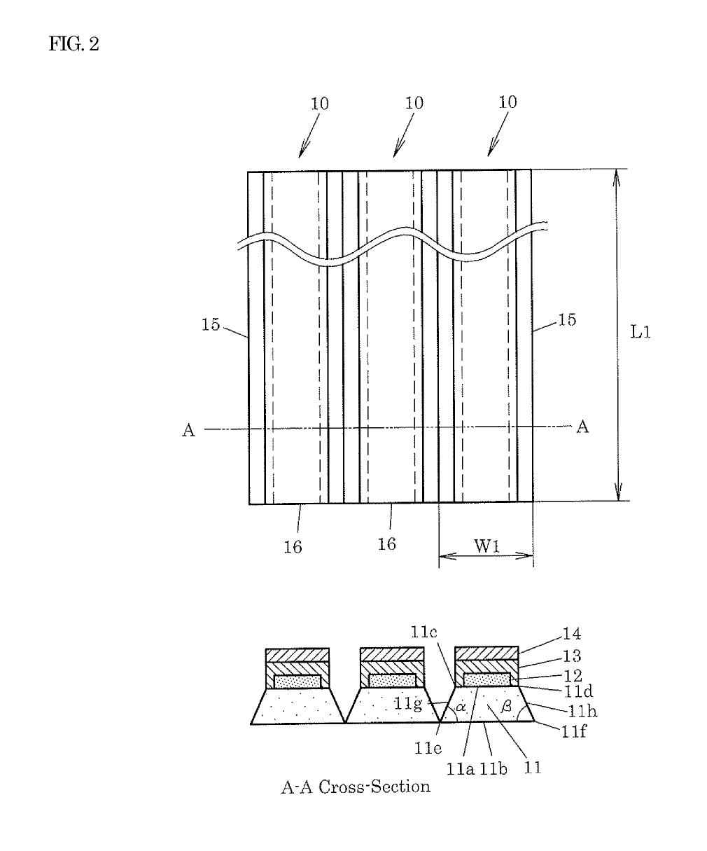

As shown in FIG. 2, the arrangement of the organic light emitting diodes 10 of the present invention in a planar reed screen fashion can create a square or nearly square rectangular light emitting element or a display, which is similar to a conventional organic light emitting diode 30. The light emitting element or the display with the organic light emitting diodes 10 of the present invention arranged in a reed screen fashion has a high light extraction efficiency, and thus produces a higher luminance than a conventional organic light emitting diode of the same size (the principle will be described later).

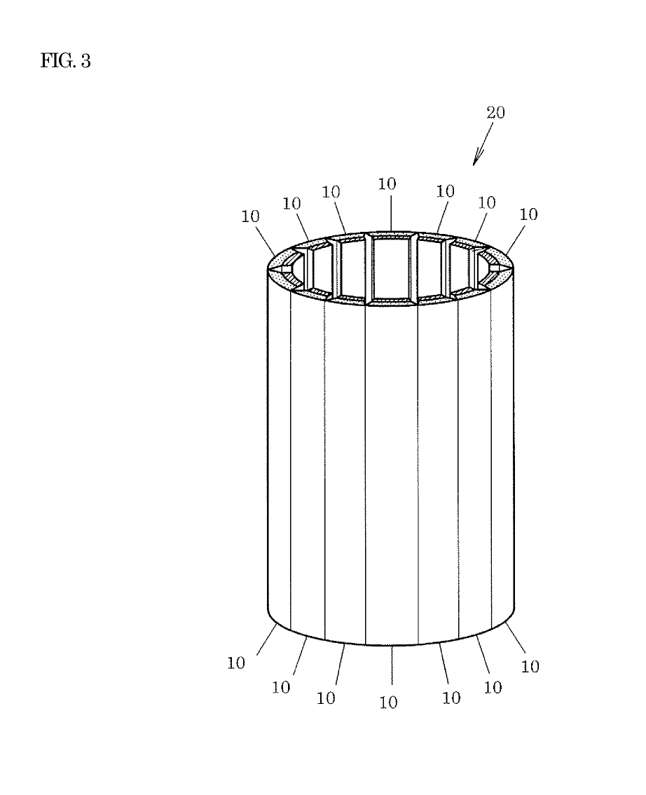

As shown in FIG. 3, the organic light emitting diodes 10 of the present invention can be arranged in a reed screen fashion to easily form a curved surface. FIG. 3 is an example of a cylindrical large-size display 20 formed by arranging a plurality of the organic light emitting diodes 10 according to the present invention in a reed screen fashion. This cylindrical large-size display 20 has a diameter of, for example, 1 m and a height of, for example, 2 m.

### [Transparent Substrate]

The material for forming the transparent substrate 11 to be used in the present invention is preferably excellent in transparency, and for example, polyester resins, polyimide resins, polycycloolefin resins, or polycarbonate resins are suitable for the material. The transparent substrate 11 to be used in the present invention preferably has a thickness of 10 μm to 500 μm.

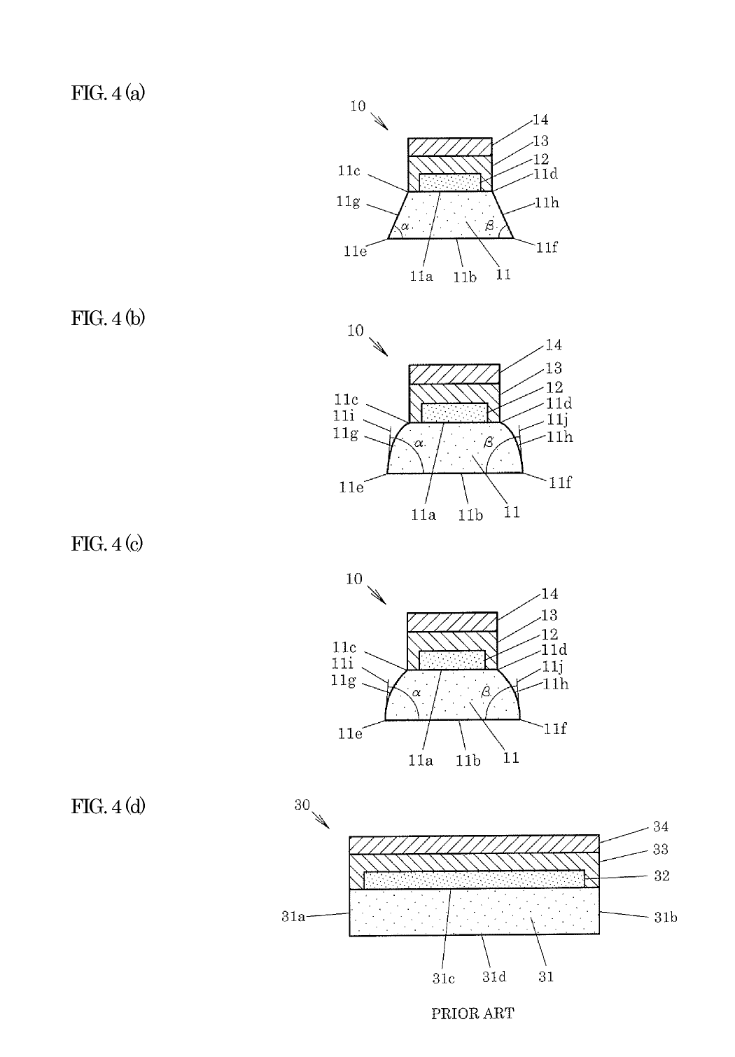

As shown in FIGS. 4(a) to 4(c), a feature of the transparent substrate 11 used for the organic light emitting diode 10 of the present invention is the shape of a cross section (a cross section along the line A-A of FIG. 1) parallel to the short side 16. In the transparent substrate 11 to be used in the present invention, the length of a side 11a (upper side) on the transparent electrode layer 12 side is shorter than the length of a side 11b (lower side) on an emission side. On the other hand, the transparent substrate 31 used for the conventional organic light emitting diode 30 has a rectangular cross section with the length of a side 31c (upper side) on the transparent electrode layer 32 side equal to the length of a side 31d (lower side) on the emission side as shown in FIG. 4(d).

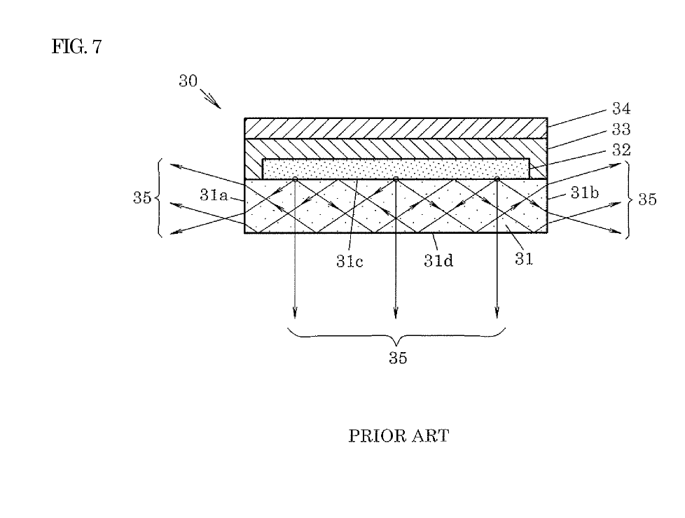

In the conventional organic light emitting diode 30 shown in FIG. 4(d), a portion of light 35 generated in the organic light emitting layer 33 is repeatedly totally reflected, and emitted to the outside from side surfaces 31a, 31b of the transparent substrate 31, as shown in FIG. 7. It is not possible to use the light 35 emitted to the outside from the side surfaces 31a, 31b of the transparent substrate 31.

In an example of the transparent substrate 11 to be used in the present invention as shown in FIG. 4(a), the line connecting an end 11c of the side 11a (upper side) on the transparent electrode layer 12 side and an end 11e of the side 11b (lower side) on the emission side, which represents a side surface 11g of the transparent substrate 11, is a straight line. In addition, the line connecting an end 11d of the side 11a (upper side) on the transparent electrode layer 12 side and an end 11f of the side 11b (lower side) on the emission side, which represents a side surface 11h of the transparent substrate 11, is a straight line. In this case, the transparent substrate 11 has a trapezoidal shape in a cross section parallel to the short side 16.

As shown in FIG. 4(a), when the transparent substrate 11 has a trapezoidal shape in a cross section parallel to the short side 16, an angle a formed by the side 11b (lower side) on the emission side and the side surface 11g and an angle β formed by the side 11b (lower side) on the emission side and the side surface 11h are preferably 40° to 50°. When the angle α is equal to the angle β, the transparent substrate 11 has the shape of an isosceles trapezoid in a cross section parallel to the short side 16.

In another example of the transparent substrate 11 to be used in the present invention as shown in FIG. 4(b), the line connecting the end 11c of the side 11a (upper side) on the transparent electrode layer 12 side and the end 11e of the side 11b (lower side) on the emission side, which represents the side surface 11g of the transparent substrate 11, is parabolic. A tangent line 11i on the side surface 11g of the transparent substrate 11 at the end 11e of the side 11b (lower side) on the emission side forms an angle α with the side 11b (lower side) on the emission side. In addition, the line connecting the end 11d of the side 11a (upper side) on the transparent electrode layer 12 side and the end 11f of the side 11b (lower side) on the emission side, which represents the side surface 11h of the transparent substrate 11, is parabolic. A tangent line 11j on the side surface 11h of the transparent substrate 11 at the end 11f of the side 11b (lower side) on the emission side forms an angle β with the side 11b (lower side) on the emission side.

In yet another example of the transparent substrate 11 to be used in the present invention as shown in FIG. 4(c), the line connecting the end 11c of the side 11a (upper side) on the transparent electrode layer 12 side and the end 11e of the side 11b (lower side) on the emission side, which represents the side surface 11g of the transparent substrate 11, is an arc. The tangent line 11i on the side surface 11g of the transparent substrate 11 at the end 11e of the side 11b (lower side) on the emission side forms an angle a with the side 11b (lower side) on the emission side. In addition, the line connecting the end 11d of the side 11a (upper side) on the transparent electrode layer 12 side and the end 11f of the side 11b (lower side) on the emission side, which represents the side surface 11h of the transparent substrate 11, is an arc. The tangent line 11j on the side surface 11h of the transparent substrate 11 at the end 11f of the side 11b (lower side) on the emission side forms an angle β with the side 11b (lower side) on the emission side.

While the cross sections of the transparent substrates 11 as shown in FIGS. 4(a) to 4(c) are bilaterally symmetric, the bilateral symmetry is not always required. In addition, there is no need for the side surface 11g of the transparent substrate 11 and the side surface 11h of the transparent substrate 11 to have the same type of curve, and one of the side surfaces may have a straight line, whereas the other thereof may have a curved line.

The cross-sectional shapes of the transparent substrates 11 as shown in FIGS. 4(a) to 4(c) can be formed by, for example, dicing or imprint processing.

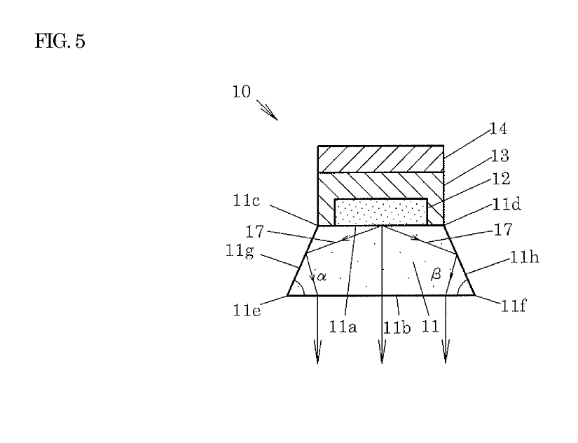

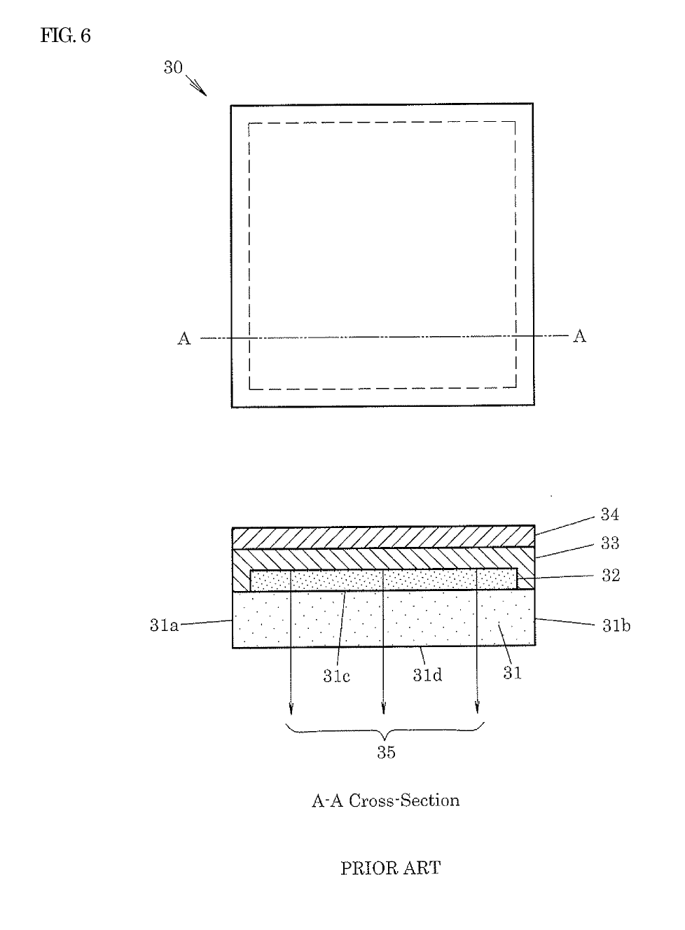

As shown in FIG. 5, in the organic light emitting diode 10 of the present invention, light 17 emitted from the transparent electrode layer 12 toward the side surfaces 11g, 11h of the transparent substrate 11 is reflected by the side surfaces 11g, 11h of the transparent substrate 11, and emitted from the side 11b (lower side) of the transparent substrate 11 on the emission side. For this reason, the emission of the light 17 from the side surfaces 11g, 11h of the transparent substrate 11 to the outside is avoided to increase the use efficiency of the light 17.

Also in the transparent substrate 11 shown in FIG. 4(b) and the transparent substrate 11 shown in FIG. 4(c), light emitted from the transparent electrode layer 12 toward the side surfaces 11g, 11h of the transparent substrate 11 is reflected by the side surfaces 11g, 11h of the transparent substrate 11, and emitted from the side 11b (lower side) of the transparent substrate 11 on the emission side. For this reason, the emission of the light from the side surfaces 11g, 11h of the transparent substrate 11 to the outside is avoided to increase the use efficiency of the light.

In the transparent substrate 11 used for the organic light emitting diode 10 of the present invention, the length of the side 11a (upper side) on the transparent electrode layer 12 side is shorter than the length of the side 11b (lower side) on the emission side in a cross section parallel to the short side 16. Furthermore, the ends 11c, 11d of the side 11a (upper side) on the transparent electrode layer 12 side and the ends 11e, 11f of the side 11b (lower side) on the emission side are connected by straight lines or curved lines. The straight lines or curved lines represent the side surfaces 11g, 11h of the transparent substrate 11.

The angles (α,β) formed by the straight lines or curved lines (the side surfaces 11g, 11h of the transparent substrate 11) and the side 11b (lower side) on the emission side are larger than 0° and smaller than 90°. It is to be noted that the angles formed by the curved lines (the side surfaces 11g, 11h of the transparent substrate 11) and the side 11b (lower side) on the emission side refer to angles formed by the tangent lines on the curved lines at the ends 11e, 11f of the side 11b (lower side) on the emission side with the side 11b (lower side) on the emission side.

The organic light emitting diode 10 of the present invention, which has the side surfaces 11g, 11h of the transparent substrate 11 with the shape as described above, can reflect light by the side surfaces 11g, 11h of the transparent substrate 11 toward the front (the side 11b on the emission side) of the transparent substrate 11, while the light is emitted from the side surfaces 31a, 31b of the transparent substrate 31 to the outside in the case of the conventional organic light emitting diode 30. As a result, the organic light emitting diode 10 of the present invention increases the use efficiency of the light.

### [Transparent Electrode Layer]

The transparent electrode layer 12 to be used in the present invention is a layer which has high transparency, and a high electric conductivity (a low resistivity). The transparent electrode layer 12 is used as an anode for injecting holes into the organic light emitting layer 13. The resistivity of the transparent electrode layer 12 is preferably 1×10[−3] Ω·cm or less (10n is represented as 10 [n] in this specification).

The material for forming the transparent electrode layer 12 to be used in the present invention is not particularly limited, but is typically an indium tin oxide (ITO) or an indium zinc oxide (IZO). These layers are formed by, for example, a vacuum deposition method or a sputtering method. The transparent electrode layer 12 to be used in the present invention preferably has a thickness of 20 nm to 500 nm.

### [Organic Light Emitting Layer]

The organic light emitting layer 13 to be used in the present invention is a layer in which injected charges are recombined and thereby excited to produce luminescence.

The material for forming the organic light emitting layer 13 for use in the present invention is not particularly limited, but is, for example, a low-molecular luminescent pigment, a π-conjugated polymer, a pigment containing polymer, or a luminescent oligomer. These layers are formed by, for example, a vacuum deposition method or a solution applying method or the like. The organic light emitting layer 13 to be used in the present invention preferably has a thickness of 10 nm to 300 nm.

### [Rear Electrode Layer]

The rear electrode layer 14 to be used in the present invention is used as a cathode for injecting electrons into the organic light emitting layer 13. The material for forming the rear electrode layer 14 to be used in the present invention is not particularly limited, but is typically an alloy containing aluminum, magnesium, or lithium. The rear electrode layer 14 to be used in the present invention preferably has a thickness of 20 nm to 500 nm.

### EXAMPLES

### Example 1

The transparent substrate 11 composed of polyethylene naphthalate of 10 mm in width, 100 μm in thickness, and 100 mm in length was prepared, and both side surfaces thereof on the long side 15 were processed by dicing into 45°-inclined surfaces. This processing produced an isosceles trapezoid in a cross section parallel to the short side 16 of the transparent substrate 11, with a basic angle α and a basic angle β each having 45°.

On the upper surface of the transparent substrate 11, the transparent electrode layer 12 composed of an indium tin oxide (ITO) of 85 nm in thickness, a hole transport layer composed of naphthyldiamine (α-NPD) of 50 nm in thickness, the organic light emitting layer 13 composed of an aluminum quinoline complex of 50 nm in thickness, and the rear electrode layer 14 composed of aluminum of 100 nm in thickness were formed sequentially by a vacuum deposition method.

Ten organic light emitting diodes 10 created in this way were prepared, and electrically connected by arranging the organic light emitting diodes 10 in a reed screen fashion as shown in FIG. 2, thereby creating a square light emitting element of 100 mm in length and width. The light extraction efficiency of this light emitting element is shown in Table 1.

### Example 2

A transparent substrate composed of square polyethylene naphthalate of 100 mm in length and width was prepared, and the side surfaces on a pair of opposed sides were processed by dicing into 45°-inclined surfaces (a basic angle α and a basic angle β each having 45°). Apart from this processing, organic light emitting diodes were created by the same method as in Example 1, and electrically connected to create a square light emitting element of 100 mm in length and width. The light extraction efficiency of this light emitting element is shown in Table 1.

### Comparative Example

A transparent substrate composed of square polyethylene naphthalate of 100 mm in length and width was prepared. The transparent substrate was rectangular in a cross section parallel to the sides of the transparent substrate because the end surfaces of the transparent substrate were not processed by dicing. Apart from this processing, organic light emitting diodes were created by the same method as in Example 1, and electrically connected to create a square light emitting element of 100 mm in length and width. The light extraction efficiency of this light emitting element is shown in Table 1.

TABLE 1

| | Number of | | | Extraction |
|---|---|---|---|---|
| | Organic Light | Cross- | Front | Efficiency |
| | Emitting Diodes | Sectional | Luminance | (Relative |
| | (pieces) | Shape | (cd/m2) | Value) |
| Example 1 | 10 | Trapezoid | 22,800 | 1.34 |
| Example 2 | 1 | Trapezoid | 18,000 | 1.06 |
| Comparative | 1 | Rectangle | 17,000 | 1.00 |
| Example | | | | |

### [Evaluation]

When Example 2 is compared with Comparative Example, the front luminance and the light extraction efficiency are slightly higher in Example 2. The reason is considered to be because light was reflected in the front direction by the two sides processed by dicing in Example 2, whereas any side was not processed by dicing in Comparative Example. Less light is leaked from the sides processed by dicing, whereas more light is leaked from the sides which are not processed by dicing.

When Example 1 is compared with Example 2, the front luminance and the light extraction efficiency are much higher in Example 1. The reason is considered to be because Example 1 has the twenty sides processed by dicing, whereas Example 2 has only the two sides processed by dicing. The larger number of sides processed by dicing increases the light toward the front, thus increasing the front luminance and the light extraction efficiency.

### [Method for Measuring Front Luminance]

A direct-current voltage of 10 V was applied to the organic light emitting diode (light emitting element) to measure the luminance in a normal direction near the center of the light emitting element, with the use of “Organic EL Luminous Efficiency Measurement System EL 1003” manufactured by PRECISE GAUGES CO., LTD.

### INDUSTRIAL APPLICABILITY

The organic light emitting diode and light emitting element according to the present invention are not particularly limited in application, and can be used for, for example, displays, electronic papers, electronic advertisements, and lighting or the like.

1. An organic light emitting diode comprising at least a transparent substrate, a transparent electrode layer, an organic light emitting layer, and a rear electrode layer in this order, wherein the organic light emitting diode has a rectangular planar shape;
the length of a long side of the rectangular shape is 5 or more times as long as the length of a short side thereof;
the length of a side of the transparent substrate on the transparent electrode layer side is shorter than the length of a side thereof on an emission side in a cross section parallel to the short side of the transparent substrate;
an end of the side of the transparent substrate on the transparent electrode layer side and an end of the side thereof on the emission side are connected by a straight line or a curved line; and
an angle formed by the straight line or the curved line and the side on the emission side is larger than 0° and smaller than 90 .

2. The organic light emitting diode according to claim 1, wherein each end of a side of the transparent substrate on the transparent electrode layer side and each end of a side thereof on the emission side are connected by a straight line in a cross section parallel to the short side of the transparent substrate; and
the cross section parallel to the short side of the transparent substrate has a trapezoidal shape.

3. The organic light emitting diode according to claim 2, wherein a cross section parallel to the short side of the transparent substrate has a trapezoidal shape; and
the trapezoidal shape has a basic angle of 40° to 50° on the emission side.

4. The organic light emitting diode according to claim 1, wherein the end of the side of the transparent substrate on the transparent electrode layer side and the end of the side thereof on the emission side are connected by a parabola.

5. The organic light emitting diode according to claim 1, wherein the end of the side of the transparent substrate on the transparent electrode layer side and the end of the side thereof on the emission side are connected by an arc.

6. The organic light emitting diode according to claim 1, wherein the transparent substrate comprises a flexible polymer film.

7. A light emitting element formed by arranging the organic light emitting diode according to claim 1 in a reed screen fashion.
